(19) United States
(12) Patent Application Publication
(10) Pub. No.: US 2026/0081110 A1
(43) Pub. Date: Mar. 19, 2026

(54) PLASMA GENERATOR BY MEANS OF RESONANT WAVEGUIDE

(71) Applicant: KOREA INSTITUTE OF FUSION ENERGY, Daejeon (KR)

(72) Inventors: Soo Ouk JANG, Sejong (KR); Tai Hyeop LHO, Seoul (KR); Yong Sup CHOI, Gunsan-si (KR); Kang Il LEE, Gunsan-si (KR); Hyun Jae PARK, Gunsan-si (KR); Jin Ha SHIN, Hwaseong-si (KR)

(73) Assignee: KOREA INSTITUTE OF FUSION ENERGY, Daejeon (KR)

(21) Appl. No.: 19/109,222

(22) PCT Filed: Sep. 6, 2023
(86) PCT No.: PCT/KR2023/013313

§ 371 Date: Mar. 6, 2025

(30) Foreign Application Priority Data
Sep. 7, 2022 (KR) 10-2022-0113477

(51) Int. Cl. H01J 37/32; H01P 5/18

(52) U.S. Cl. CPC H01J 37/32229; H01J 37/32201; H01P 5/181

(57) ABSTRACT

A plasma generator by means of a resonant waveguide is disclosed. The plasma generator comprises: an annular or elliptical central waveguide that includes a plurality of slots on the inner side surface thereof; a first incident waveguide that is tangentially connected to the central waveguide to enable electromagnetic wave communication; an electromagnetic wave supply unit that transmits electromagnetic waves to the incident waveguide; and a plasma chamber that has an electromagnetic wave incident window which is positioned on an outlet side of the slots to seal the inside of the central waveguide, and through which electromagnetic waves introduced through the slots may be radiated to the outside.

### BACKGROUND

### Field of the Disclosure

The present disclosure relates to a plasma generating apparatus using a resonant waveguide, and more particularly, to a plasma generating apparatus using a resonant waveguide capable of generating plasma of a uniform large area.

### Description of Related Art

In general, it is very efficient to use a roll-to-roll scheme to perform plasma treatment on a large-area base material, especially, to perform an process of an OLED thin film with flexibility or perform the plasma treatment on a functional fabric.

Since the roll-to-roll scheme is performed while scanning from one end to the other end of the base material, a plasma source having a size capable of covering the entire base material is required. However, a microwave plasma source according to the related art has a length or diameter limited to a wavelength of the microwave, so that there is a limit to perform the plasma treatment on the base material having a predetermined size or greater.

In order to solve this problem, a plasma source using electromagnetic waves generated in an oval shape of a track shape elongate in one direction is fabricated to be used to plasma-process a large-area object to be processed. However, it is difficult to apply power to uniformly generate the plasma in the longitudinal direction of the elongate track shape, and thus it is difficult to generate the uniform large-area plasma.

### SUMMARY OF THE INVENTION

Accordingly, a purpose of the present disclosure is to provide a plasma generating apparatus using a resonant waveguide capable of generating plasma of a large area in which power of electromagnetic waves is uniformly maintained in an entire area of the resonant waveguide and plasma density and uniformity are maintained in a plasma chamber.

A plasma generating apparatus using a resonant waveguide according to an embodiment of the present disclosure includes an annular or elliptical central waveguide including a plurality of slots defined in an inner side surface thereof; a first incoming waveguide tangentially connected to the central waveguide such that an electromagnetic wave communicates therebetween; an electromagnetic wave supply configured to transmit electromagnetic waves to the incoming waveguide; and a plasma chamber having an electromagnetic wave transmission window located on outlets of the slots so as to seal an inside of the central waveguide, wherein the electromagnetic waves introduced through the slots into the electromagnetic wave transmission window are radiated through the electromagnetic wave transmission window into the plasma chamber. The electromagnetic waves are input to the central waveguide in a normal direction, and are resonated with each other while traveling in a rotating manner along the central waveguide so that the resonating strong electromagnetic wave is generated in the central waveguide and then is emitted through the slots.

In one embodiment, the plasma generating apparatus further comprises a second incoming waveguide tangentially connected to the center waveguide such that an electromagnetic wave communicates therebetween, wherein the second incoming waveguide and the first incoming waveguide are arranged in a symmetrical manner with each other around a center point of an annular or elliptical shape of the center waveguide. When the incoming waveguides are arranged with each other in such a diagonal line, the wave in the central waveguide propagates in the same direction to induce resonance, and at the same time, the disadvantage in which the further away from the incoming waveguide, the smaller the power is may be removed. The central waveguide induces the resonance to reduce loss of the electromagnetic waves, and at the same time induces the plasma generation in the chamber under the uniform distribution of the electromagnetic waves. The plasma generation source of the present disclosure provides a structure in which the plasma is generated in the chamber through the electromagnetic waves being applied through the plurality of slots defined at a designated position in a linear section of the central waveguide to the chamber.

A relatively strong electromagnetic wave is generated near the incoming waveguide, and the electromagnetic wave becomes weaker as it travels away from the incoming waveguide, thereby causing the conventional problem of plasma non-uniformity in the linear section. To solve this problem, the present disclosure introduces a structure in which the electromagnetic waves are incident in both directions. To this end, the first incoming waveguide and the second incoming waveguide are arranged in a symmetrical manner with each other around a center point of the annular or elliptical shape of the central waveguide such that the microwave from the first incoming waveguide travels in the same direction as the travel direction of the microwave from the second incoming waveguide.

In an embodiment, the plasma generating apparatus further comprises: a third incoming waveguide tangentially connected to the center waveguide such that an electromagnetic wave communicates therebetween, wherein the third incoming waveguide and the first incoming waveguide are arranged in the same row, and the third incoming waveguide parallel and the second incoming waveguide are arranged in the same column; and a fourth incoming waveguide tangentially connected to the center waveguide such that an electromagnetic wave communicates therebetween, wherein the fourth incoming waveguide and the second incoming waveguide are arranged in the same row, and the fourth incoming waveguide parallel and the first incoming waveguide are arranged in the same column. In the structure of the above four incoming waveguides, two microwaves are incident in different directions, such that a standing wave may be induced inside the waveguide. The standing waves may be generated to induce the electromagnetic waves of the uniform intensity in the slots. In addition, the first, second, third, and fourth incoming waveguides are respectively positioned at upper, lower, left, and right positions of the central waveguide and in an symmetrical manner with each other around the center of the central waveguide and are connected to the central waveguide in a tangential manner, thereby reducing a strong electric field intensity non-uniformity in the vicinity of each of the different incoming waveguides.

In one embodiment, the central waveguide includes: a first linear rectangular waveguide; a second linear rectangular waveguide parallel to the first linear rectangular waveguide; a first curved rectangular waveguide connecting one end of the first linear rectangular waveguide and one end of the second linear rectangular waveguide to each other in an electromagnetic wave communication manner; and a second curved rectangular waveguide connecting the other end of the first linear rectangular waveguide and the other end of the second linear rectangular waveguide to each other in an electromagnetic wave communication manner, wherein the first incoming waveguide is connected to one end of the first linear rectangular waveguide so as to be capable of electromagnetic wave communication in parallel with the first curved rectangular waveguide.

In one embodiment, the plasma generating apparatus further comprises a second incoming waveguide tangentially connected to the center waveguide such that an electromagnetic wave communicates therebetween, wherein the second incoming waveguide and the first incoming waveguide are arranged in a symmetrical manner with each other around a center point of an annular or elliptical shape of the center waveguide, wherein the second incoming waveguide is connected to an end of the second linear rectangular waveguide so as to be capable of electromagnetic wave communication in parallel with the second curved rectangular waveguide.

In one embodiment, the plasma generating apparatus further comprises: a third incoming waveguide tangentially connected to the center waveguide such that an electromagnetic wave communicates therebetween, wherein the third incoming waveguide and the first incoming waveguide are arranged in the same row, and the third incoming waveguide parallel and the second incoming waveguide are arranged in the same column; and a fourth incoming waveguide tangentially connected to the center waveguide such that an electromagnetic wave communicates therebetween, wherein the fourth incoming waveguide and the second incoming waveguide are arranged in the same row, and the fourth incoming waveguide parallel and the first incoming waveguide are arranged in the same column, wherein the third incoming waveguide is connected to an end of the first linear rectangular waveguide so as to be capable of electromagnetic wave communication in parallel with the second curved rectangular waveguide, wherein the fourth incoming waveguide is connected to an end of the second linear rectangular waveguide so as to be capable of electromagnetic wave communication in parallel with the first curved rectangular waveguide.

In one embodiment, each of the linear and curved rectangular waveguides operates in a TE mode, wherein one of two surfaces of each of the linear and curved rectangular waveguides is perpendicular to an electric field generated in each of the linear and curved rectangular waveguides and vertically extends and faces inwardly of the annular or elliptical shape of the center waveguide, wherein the slots are defined in an inner side surface of each of the linear rectangular waveguides.

In one embodiment, the linear rectangular waveguide is embodied as a WR430 waveguide, wherein the curved rectangular waveguide is embodied as a WR284 waveguide, wherein the incoming waveguide is embodied as a WR340 waveguide.

In one embodiment, the plasma generating apparatus further comprises each guide wall extending into each linear rectangular waveguide from a distal end of an outer side surface of each curved rectangular waveguide perpendicular to an electric field generated in each curved rectangular waveguide, wherein the distal end thereof corresponds to a distal end of each corresponding linear rectangular waveguide.

The guide wall prevents the electromagnetic waves traveling through the resonance structure from flowing back to the incoming waveguide. The guide wall prevents the electromagnetic waves traveling from the curved rectangular waveguide WR284 to the linear rectangular waveguide WR430 from flowing backward to the incoming waveguide WR340. In addition, the length and the angle of the guide wall may be adjusted to induce a hollow structure in which the electromagnetic waves incident from the incoming waveguide having a tapered shape and the electromagnetic waves travelling through the internal resonance structure of the annular or elliptical central waveguide are effectively transmitted, without causing loss due to the interference with each other.

According to the plasma generating apparatus using the resonant waveguide of the present disclosure, the power of the electromagnetic waves is uniformly maintained throughout the entire section of the resonant waveguide, and accordingly, the electromagnetic waves of the uniform power are radiated into the plasma chamber through the plurality of slots, thereby generating the plasma of a large area in which density and uniformity thereof are maintained in the plasma chamber.

### BRIEF DESCRIPTION OF THE DRAWINGS

FIG. 1 is a cross-sectional view illustrating a configuration of a plasma generating apparatus using a resonant waveguide according to an embodiment of the present disclosure.

FIG. 2 is a perspective view showing an appearance of a central waveguide and an incoming waveguides shown in FIG. 1.

FIG. 3 is a cross-sectional view showing transmission of electromagnetic waves and plasma generation of a plasma generating apparatus using a resonant waveguide according to an embodiment of the present disclosure.

### DETAILED DESCRIPTION OF THE INVENTION

Hereinafter, a plasma generating apparatus using a resonant waveguide according to an embodiment of the present disclosure will be described in detail with reference to the accompanying drawings. Since the present disclosure may be variously changed and may have various forms, specific embodiments are illustrated in the drawings and will be described in detail herein. However, this is not intended to limit the present disclosure to a specific disclosed form, and it should be understood that the present disclosure includes all modifications, equivalents, and substitutes included in the spirit and technical scope of the present disclosure. Similar reference numerals are used for similar components while describing the drawings. In the accompanying drawings, the dimensions of the structures are shown in an enlarged view for clarity of the present disclosure.

Terms such as first, second, and the like may be used to describe various components, but the components should not be limited by the terms. The terms are used only for the purpose of distinguishing one component from another component. For example, without departing from the scope of the present disclosure, a first component may be referred to as a second component, and similarly, a second component may also be referred to as a first component.

The terminology used herein is intended for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises”, “comprising”, “includes”, and “including” when used in this specification, specify the presence of the stated features, integers, operations, elements, and/or components, but do not preclude the presence or addition of one or greater other features, integers, operations, elements, components, and/or portions thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

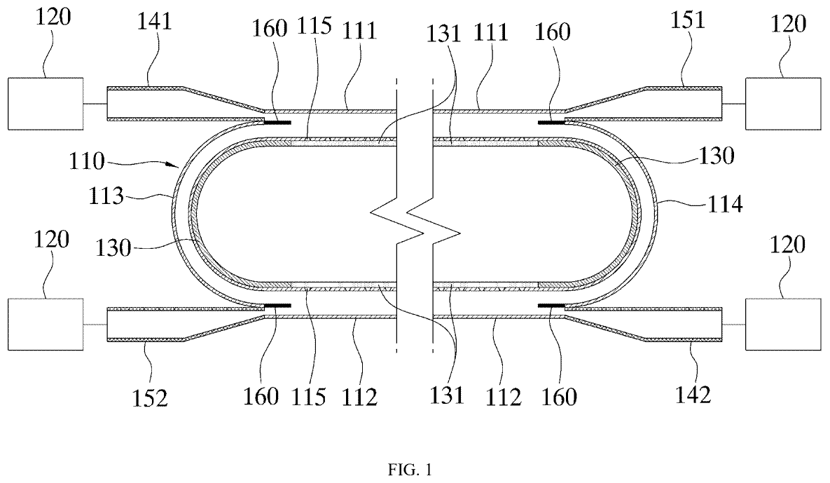

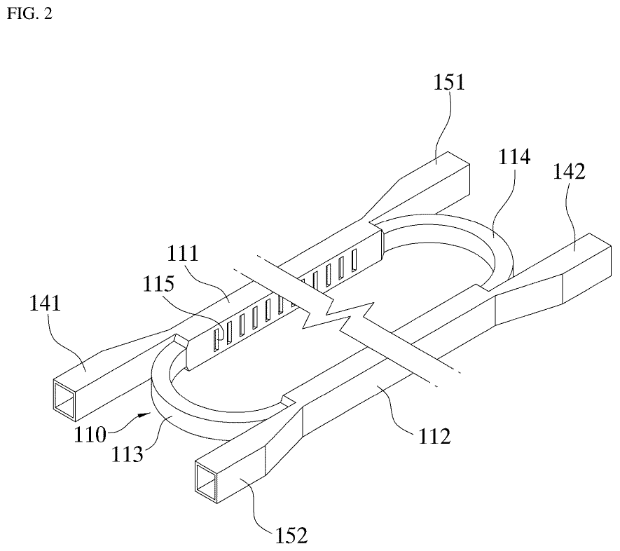

FIG. 1 is a cross-sectional view illustrating a configuration of a plasma generating apparatus using a resonant waveguide according to an embodiment of the present disclosure, and FIG. 2 is a perspective view illustrating an appearance of a central waveguide and an incoming waveguide illustrated in FIG. 1.

Referring to FIGS. 1 and 2, the resonant waveguide according to an embodiment of the present disclosure may include a central waveguide 110, a first incoming waveguide 141, a first electromagnetic wave supply 120, and a plasma chamber 130.

The central waveguide 110 may be provided in a form of a track to transmit electromagnetic waves in a clockwise or counterclockwise direction. For example, the central waveguide 110 may be provided in an annular or elliptical shape. The central waveguide 110 is a rectangular waveguide.

Specifically, the central waveguide 110 may include a first linear rectangular waveguide 111, a second linear rectangular waveguide 112, a first curved rectangular waveguide 113, and a second curved rectangular waveguide 114.

The first linear rectangular waveguide 111 is a waveguide extending linearly in one direction of the central waveguide 110.

The second linear rectangular waveguide 112 is a waveguide of the central waveguide 110 parallel to the first linear rectangular waveguide 111.

The first curved rectangular waveguide 113 constitutes one side of the central waveguide 110, and extends from one end of each of the first linear rectangular waveguide 111 and the second linear rectangular waveguide 112 so as to connect one end of the first linear rectangular waveguide 111 to one end of the second linear rectangular waveguide 112 in an electromagnetic wave communication manner.

The second curved rectangular waveguide 114 constitutes the other side of the central waveguide 110, and extends from the other end of each of the first linear rectangular waveguide 111 and the second linear rectangular waveguide 112 so as to connect the other end of the first linear rectangular waveguide 111 to the other end of the second linear rectangular waveguide 112 in an electromagnetic wave communication manner.

In this structure of the central waveguide 110, the first and second linear rectangular waveguides 112 and the first and second curved rectangular waveguides 114 operate in a TE mode. The central waveguide 110 may be constructed such that one of two surfaces of each of the first and second linear rectangular waveguides 111 and 112 and the first and second curved rectangular waveguides 113 and 114 perpendicular to the electric field generated therein extends vertically so as to face inwardly of the annular or elliptical shape of the central waveguide 110. In this case, among the two opposite surfaces of each of the rectangular waveguides 111, 112, 113, and 114 which extend vertically, one surface facing inwardly of the annular or elliptical shape of the central waveguide 110 is defined as the inner side surface of the central waveguide 110, and the other surface facing outwardly of the annular or elliptical shape of the central waveguide 110 is defined as an outer side surface of the central waveguide 110.

In an embodiment, the first and second linear rectangular waveguides 111 and 112 may be provided as WR430 waveguides, and the first and second curved rectangular waveguides 113 and 114 may be provided as WR284 waveguides.

The central waveguide 110 may include a plurality of slots 115. The slot 115 may be provided to radiate electromagnetic waves in the central waveguide 110 to the outside. For example, the plurality of slots 115 may be arranged so as to be spaced from each other by a regular spacing and may be defined in the inner side surface of each of the first linear rectangular waveguide 111 and the second linear rectangular waveguide 112. There is no particular limitation on the shape of the slot 115. For example, the slot may be constructed such that a width thereof increases as the slot extends from an inner space of each of the first linear rectangular waveguide 111 and the second linear rectangular waveguide 112 toward the inner side surface of each of the first linear rectangular waveguide 111 and the second linear rectangular waveguide 112.

The first incoming waveguide 141 receives electromagnetic waves and transmits the same into the central waveguide 110. The first incoming waveguide 141 may be tangentially connected to the central waveguide 110 to enable electromagnetic wave communication therebetween. In this case, the first incoming waveguide 141 may be connected to a distal end of the first linear rectangular waveguide 111 connected to the first curved rectangular waveguide 113 so as to be capable of electromagnetic wave communication in parallel with the first curved rectangular waveguide 113. The electromagnetic wave incident from the first incoming waveguide 141 may be incident on the first linear rectangular waveguide 111 and then pass through the second curved rectangular waveguide 114 and thus may be transmitted in a clockwise direction, and may then pass through the second linear rectangular waveguide 112 and the second curved rectangular waveguide 114. In an example, the first incoming waveguide 141 may be constructed such that one surface thereof connected to the outer side surface of the first linear rectangular waveguide 111 is inclined toward the first linear rectangular waveguide 111 such that a portion thereof connected to the first linear rectangular waveguide 111 is tapered.

The first electromagnetic wave supply 120 may supply the electromagnetic waves to the first incoming waveguide 141. For example, the first electromagnetic wave supply 120 may include a power supply and a magnetron oscillating the electromagnetic waves to the first incoming waveguide 141. A plurality of electromagnetic wave supplies 120 may be provided, and in this case, each of the electromagnetic wave supplies 120 may transmit the electromagnetic waves to each of the first incoming waveguide 141 and the second to fourth incoming waveguides 152 to be described later.

The plasma chamber 130 may be defined along an inner circumference of the central waveguide 110, may be located inwardly of the central waveguide 110. The electromagnetic waves incident from the central waveguide 110 may be transmitted into the plasma chamber 130. For example, the plasma chamber 130 may be provided in an annular or elliptical shape.

The plasma chamber 130 may have an electromagnetic wave transmission window 131 through which the electromagnetic waves are incident into the plasma chamber 130. The electromagnetic wave transmission window 131 is disposed to face the plurality of slots 115 of the central waveguide 110. That is, the electromagnetic wave transmission window 131 may be located at an outlet side of each of the plurality of slots 115 so as to seal the inside of the central waveguide 110. The electromagnetic waves introduced through the plurality of slots 115 into the electromagnetic wave transmission window 131 are radiated through the electromagnetic wave transmission window 131 into the inside of the plasma chamber 130. The electromagnetic wave transmission window 131 may be provided in a plural manner. In this case, each of the plurality of electromagnetic wave transmission windows 131 may cover the outlets of the plurality of slots 115 defined in each of the first and second linear rectangular waveguides 111 and 112 so as to face each of the inner side surface of the first linear rectangular waveguide 111 and the inner side surface of the second linear rectangular waveguide 112.

In one example, the plasma generating apparatus using the resonant waveguide according to an embodiment of the present disclosure may further include the second incoming waveguide 142.

The second incoming waveguide 142 allows the electromagnetic waves incident thereto to be transmitted into the central waveguide 110. The second incoming waveguide 142 may be tangentially connected to the central waveguide 110 to enable electromagnetic wave communication therebetween. In this case, the second incoming waveguide 142 may be connected to a distal end of the second linear rectangular waveguide 112 connected to the second curved rectangular waveguide 114 so as to be capable of electromagnetic wave communication in parallel with the second curved rectangular waveguide 114. The first incoming waveguide 141 and second incoming waveguide 142 may be arranged in a symmetrical manner with each other around a center point of the annular or elliptical shape of the central waveguide 110. In an embodiment, the second incoming waveguide 142 and the first incoming waveguide 141 may be arranged in a diagonal direction. The electromagnetic wave incident from the second incoming waveguide 142 may be incident on the second linear rectangular waveguide 112 and pass through the first curved rectangular waveguide 113 and thus be transmitted in a clockwise direction, and may then pass through the first linear rectangular waveguide 111 and the second curved rectangular waveguide 114. The frequency of the electromagnetic wave incident through the second incoming waveguide 142 may be equal to the frequency of the electromagnetic wave incident through the first incoming waveguide 141. In an example, the second incoming waveguide 142 may be constructed such that one surface thereof connected to the outer side surface of the second linear rectangular waveguide 112 is inclined toward the second linear rectangular waveguide 112 such that a portion thereof connected to the second linear rectangular waveguide 112 is tapered.

In one example, the plasma generating apparatus using the resonant waveguide according to an embodiment of the present disclosure may further include the third incoming waveguide 151 and the fourth incoming waveguide 152.

The third incoming waveguide 151 allows electromagnetic waves incident thereto to be transmitted into the central waveguide 110. The third incoming waveguide 151 and the first incoming waveguide 141 may be arranged in a line, and the third incoming waveguide 151 may be tangentially connected to the center waveguide 110 to enable electromagnetic wave communication therebetween. In this case, the third incoming waveguide 151 may be connected to a distal end of the first linear rectangular waveguide 111 connected to the second curved rectangular waveguide 114 so as to be capable of electromagnetic wave communication in parallel with the second curved rectangular waveguide 114. The electromagnetic wave incident from the third incoming waveguide 151 may be incident on the first linear rectangular waveguide 111 and then pass through the first curved rectangular waveguide 113 and thus be transmitted in a counterclockwise direction, and may then pass through the second linear rectangular waveguide 112 and the second curved rectangular waveguide 114. The frequency of the electromagnetic wave incident on the third incoming waveguide 151 may be equal to the frequency of the electromagnetic wave incident on the first incoming waveguide 141 and the second incoming waveguide 142. In this case, the electromagnetic wave incident on the third incoming waveguide 151 may be an electromagnetic wave having the same frequency, the same amplitude, and the same phase angle as those of each of the electromagnetic wave incident on the first incoming waveguide 141 and the electromagnetic wave incident on the second incoming waveguide 142. In an example, the third incoming waveguide 151 may be constructed such that one surface thereof connected to the outer side surface of the first linear rectangular waveguide 111 is inclined toward the first linear rectangular waveguide 111 such that a portion thereof connected to the first linear rectangular waveguide 111 is tapered.

The fourth incoming waveguide 152 allows electromagnetic waves incident thereto to be transmitted into the central waveguide 110. The fourth incoming waveguide 152 and the second incoming waveguide 142 may be arranged in a line. The fourth incoming waveguide 152 may be tangentially connected to the center waveguide 110 to enable electromagnetic wave communication therebetween. In this case, the fourth incoming waveguide 152 may be connected to a distal end of the second linear rectangular waveguide 112 connected to the first curved rectangular waveguide 113 so as to be capable of electromagnetic wave communication in parallel with the first curved rectangular waveguide 113. The electromagnetic wave incident on the fourth incoming waveguide 152 may be incident on the second rectilinear rectangular waveguide 112 and then pass through the second curved rectangular waveguide 114, and thus be transmitted in a counterclockwise direction and then pass through the first rectilinear rectangular waveguide 111 and the first curved rectangular waveguide 113. The frequency of the electromagnetic wave incident on the fourth incoming waveguide 152 may be equal to the frequency of the electromagnetic wave incident on the third incoming waveguide 151. In an example, the fourth incoming waveguide 152 may be constructed such that one surface thereof connected to the outer side surface of the second linear rectangular waveguide 112 is inclined toward the second linear rectangular waveguide 112 such that a portion thereof connected to the second linear rectangular waveguide 112 is tapered.

In an embodiment, each of the first to fourth incoming waveguides 152 may be embodied as a WR340 waveguide.

In one example, the plasma generating apparatus using the resonant waveguide according to an embodiment of the present disclosure may further include a guide wall 160.

The guide wall 160 may be provided at each connection point at which each of the first to fourth incoming waveguides 152 is connected to the central waveguide 110 so as to communicate electromagnetic waves therebetween. Accordingly, the guide wall 160 may include first to fourth guide walls 160.

The first guide wall 160 may further extend into the first linear rectangular waveguide 111 from a distal end of the outer side surface as one of the two surfaces of the first curved rectangular waveguide 113 perpendicular to the electric field in the first curved rectangular waveguide 113, wherein the distal end thereof corresponds to the distal end of the first linear rectangular waveguide 111.

The second guide wall 160 may further extend into the second linear rectangular waveguide 112 from a distal end of the outer side surface as one of the two surfaces of the second curved rectangular waveguide 114 perpendicular to the electric field in the second curved rectangular waveguide 114, wherein the distal end thereof corresponds to the distal end of the second linear rectangular waveguide 112.

The third guide wall 160 may further extend into the first linear rectangular waveguide 111 from a distal end of the outer side surface as one of the two surfaces of the second curved rectangular waveguide 114 perpendicular to the electric field in the second curved rectangular waveguide 114, wherein the distal end thereof corresponds to the distal end of the first linear rectangular waveguide 111.

The fourth guide wall 160 may further extend into the second linear rectangular waveguide 112 from a distal end of the outer side surface as one of the two surfaces of the first curved rectangular waveguide 113 perpendicular to the electric field in the first curved rectangular waveguide 113, wherein the distal end thereof corresponds to the distal end of the second linear rectangular waveguide 112.

When the electromagnetic wave is incident from each of the first incoming waveguide 141 and the second incoming waveguide 142 and is transmitted in the center waveguide 110 in a clockwise direction, or when the electromagnetic wave is incident from each of the third incoming waveguide 151 and the fourth incoming waveguide 152 and is transmitted in a counterclockwise direction in the center waveguide 110, each of the first to fourth guide walls 160 functions as a blocking wall between each of the distal ends of the first curved rectangular waveguide 113 and the second curved rectangular waveguide 114 and each of the distal ends of the first to fourth incoming waveguides 141, 142, 151 and 152 at each point at which each of the first to fourth incoming waveguides 141, 142, 151 and 152 are connected to each of the first curved rectangular waveguide 113 and the second curved rectangular waveguide 114, and guides the electromagnetic waves so that the traveling direction of the electromagnetic waves is maintained, thereby preventing the electromagnetic waves from backflowing from the center waveguide 110 toward the first to fourth incoming waveguides 141, 142, 151 and 152.

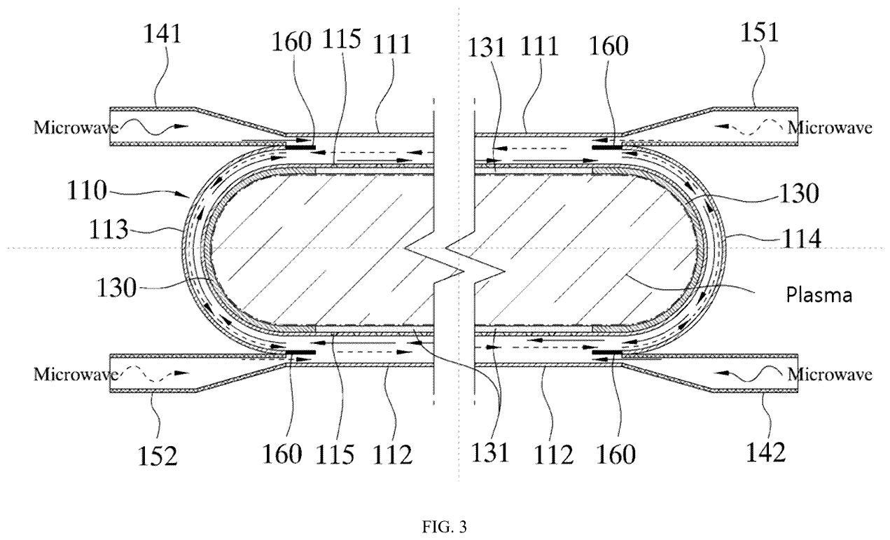

Hereinafter, an electromagnetic wave transmission process and a plasma generation process of the plasma generating apparatus using the resonant waveguide according to an embodiment of the present disclosure will be described with reference to FIG. 3. FIG. 3 is a cross-sectional view showing transmission of electromagnetic waves and plasma generation of a plasma generating apparatus using a resonant waveguide according to an embodiment of the present disclosure.

The electromagnetic waves are incident through the first to fourth incoming waveguides 152 into the central waveguide 110 for plasma generation in the plasma chamber 130.

The electromagnetic wave incident from the first incoming waveguide 141 is incident into the first linear rectangular waveguide 111 of the central waveguide 110 and then is transmitted via the second curved rectangular waveguide 114 and toward the second linear rectangular waveguide 112.

The electromagnetic wave incident from the second incoming waveguide 142 is incident into the second linear rectangular waveguide 112 of the central waveguide 110 and then is transmitted via the first curved rectangular waveguide 113 and toward the first linear rectangular waveguide 111.

The electromagnetic wave incident through the first incoming waveguide 141 and the electromagnetic wave incident through the second incoming waveguide 142 have the same frequency, and are merged with each other and then transmitted in the same direction (clockwise).

The electromagnetic wave incident from the third incoming waveguide 151 is incident into the first linear rectangular waveguide 111 of the central waveguide 110 and then is transmitted via the first curved rectangular waveguide 113 and toward the second linear rectangular waveguide 112.

The electromagnetic wave incident from the fourth incoming waveguide 152 is incident into the second linear rectangular waveguide 112 of the central waveguide 110 and then is transmitted via the second curved rectangular waveguide 114 and toward the first linear rectangular waveguide 111.

The electromagnetic wave incident through the third incoming waveguide 151 and the electromagnetic wave incident through the fourth incoming waveguide 152 have the same frequency, and are merged with each other and transmitted in the same direction (counterclockwise direction). In addition, the electromagnetic waves incident through the third incoming waveguide 151 and the fourth incoming waveguide 152 may have the same frequency, the same amplitude, and the same phase angle as those of the electromagnetic waves incident through the first incoming waveguide 141 and the second incoming waveguide 142.

Accordingly, the electromagnetic waves incident through the first incoming waveguide 141 and the second incoming waveguide 142 and the electromagnetic waves incident through the third incoming waveguide 151 and the fourth incoming waveguide 152 may travel in opposite directions to each other, so that interference therebetween may occur, and a standing wave may be induced in the central waveguide 110 as the electromagnetic waves have the same frequency, the same amplitude, and the same phase angle.

Subsequently, the electromagnetic waves in the central waveguide 110 may be introduced into the plurality of slots 115 arranged and defined in the first linear rectangular waveguide 111 and the second linear rectangular waveguide 112, and then may be radiated into the plasma chamber 130 through the electromagnetic wave transmission window 131 of the plasma chamber 130, such that the plasma may be generated in the plasma chamber 130.

In the process of transmitting the electromagnetic wave and the process of generating the plasma, the power of the electromagnetic wave incident from the first incoming waveguide 141 may decrease as the distance from the first incoming waveguide 141 increases. However, the electromagnetic wave is incident from the second incoming waveguide 142 and then travels in the same direction as the travel direction of the electromagnetic wave incident from the first incoming waveguide 141 and the then is merged with the electromagnetic wave incident from the first incoming waveguide 141, such that the power of the electromagnetic wave in the entire section of the central waveguide 110 may be uniformly maintained as the electromagnetic wave incident from the second incoming waveguide 142 and the electromagnetic wave incident from the first incoming waveguide 141 having the same travel direction are merged with each other even though the power of the electromagnetic wave incident from the first incoming waveguide 141 gradually decreases as the distance from the first incoming waveguide 141 increases.

The principle under which the problem that the power of the electromagnetic wave decreases is solved may be equally applied to the electromagnetic wave incident through the third incoming waveguide 151 and transmitted into the central waveguide 110 and the electromagnetic wave incident through the fourth incoming waveguide 152 and transmitted into the central waveguide 110.

In addition, the electromagnetic waves incident from the third incoming waveguide 151 and the fourth incoming waveguide 152 and then transmitted into the central waveguide 110 have the same attribute and the opposite travel direction as and to those of the electromagnetic waves incident from the first incoming waveguide 141 and the second incoming waveguide 142 and then transmitted into the central waveguide 110. Thus, the standing wave is induced in the central waveguide 110, and the electromagnetic waves of the uniform power may be introduced through the plurality of slots 115 into the plasma chamber.

As described above, the power of the electromagnetic wave is uniformly maintained in the entire section of the central waveguide 110 and then the electromagnetic wave of the uniform power is introduced through the plurality of slots 115 into the plasma chamber 130, such that the plasma having the density and uniformity maintained in the entire area of the plasma chamber 130 may be generated.

Further, the guide wall 160 is provided in the central waveguide 110 at each point at which each of the first to fourth incoming waveguides 152 is connected to the central waveguide 110, such that the traveling direction of the electromagnetic wave in the central waveguide 110 may be maintained, and the electromagnetic wave may be prevented from flowing backward to the first to fourth incoming waveguides 152. This may further prevent the power of the electromagnetic wave in the central waveguide 110 from being reduced as the electromagnetic wave in the central waveguide 110 flows backward in the direction opposite to the incident direction of the electromagnetic wave.

In addition, since each of the central waveguide 110 and the plasma chamber 130 is provided in the annular or elliptical shape, the large-area plasma may be generated.

The description of the presented embodiments is provided so that any person having ordinary skill in the art of the present disclosure can use or practice the present disclosure. Various variations of these embodiments will be apparent to those of ordinary skill in the art, and the general principles defined herein may be applied to other embodiments without departing from the scope of the present disclosure. Thus, the present disclosure is not limited to the embodiments set forth herein, but should be interpreted in the broadest range consistent with the principles and novel features set forth herein.

1. A plasma generating apparatus using a resonant waveguide, the apparatus comprising:
an annular or elliptical central waveguide including a plurality of slots defined in an inner side surface thereof;
a first incoming waveguide tangentially connected to the central waveguide such that an electromagnetic wave communicates therebetween;
an electromagnetic wave supply configured to transmit electromagnetic waves to the incoming waveguide; and
a plasma chamber having an electromagnetic wave transmission window located on outlets of the slots so as to seal an inside of the central waveguide, wherein the electromagnetic waves introduced through the slots into the electromagnetic wave transmission window are radiated through the electromagnetic wave transmission window into the plasma chamber.

2. The plasma generating apparatus using the resonant waveguide of claim 1, wherein the plasma generating apparatus further comprises a second incoming waveguide tangentially connected to the center waveguide such that an electromagnetic wave communicates therebetween, wherein the second incoming waveguide and the first incoming waveguide are arranged in a symmetrical manner with each other around a center point of an annular or elliptical shape of the center waveguide.

3. The plasma generating apparatus using the resonant waveguide of claim 2, wherein the plasma generating apparatus further comprises:
a third incoming waveguide tangentially connected to the center waveguide such that an electromagnetic wave communicates therebetween, wherein the third incoming waveguide and the first incoming waveguide are arranged in the same row, and the third incoming waveguide parallel and the second incoming waveguide are arranged in the same column; and
a fourth incoming waveguide tangentially connected to the center waveguide such that an electromagnetic wave communicates therebetween, wherein the fourth incoming waveguide and the second incoming waveguide are arranged in the same row, and the fourth incoming waveguide parallel and the first incoming waveguide are arranged in the same column.

4. The plasma generating apparatus using the resonant waveguide of claim 1, wherein the central waveguide includes:
a first linear rectangular waveguide;
a second linear rectangular waveguide parallel to the first linear rectangular waveguide;
a first curved rectangular waveguide connecting one end of the first linear rectangular waveguide and one end of the second linear rectangular waveguide to each other in an electromagnetic wave communication manner; and
a second curved rectangular waveguide connecting the other end of the first linear rectangular waveguide and the other end of the second linear rectangular waveguide to each other in an electromagnetic wave communication manner,
wherein the first incoming waveguide is connected to one end of the first linear rectangular waveguide so as to be capable of electromagnetic wave communication in parallel with the first curved rectangular waveguide.

5. The plasma generating apparatus using the resonant waveguide of claim 4, wherein the plasma generating apparatus further comprises a second incoming waveguide tangentially connected to the center waveguide such that an electromagnetic wave communicates therebetween, wherein the second incoming waveguide and the first incoming waveguide are arranged in a symmetrical manner with each other around a center point of an annular or elliptical shape of the center waveguide,
wherein the second incoming waveguide is connected to an end of the second linear rectangular waveguide so as to be capable of electromagnetic wave communication in parallel with the second curved rectangular waveguide.

6. The plasma generating apparatus using the resonant waveguide of claim 5, wherein the plasma generating apparatus further comprises:
a third incoming waveguide tangentially connected to the center waveguide such that an electromagnetic wave communicates therebetween, wherein the third incoming waveguide and the first incoming waveguide are arranged in the same row, and the third incoming waveguide parallel and the second incoming waveguide are arranged in the same column; and
a fourth incoming waveguide tangentially connected to the center waveguide such that an electromagnetic wave communicates therebetween, wherein the fourth incoming waveguide and the second incoming waveguide are arranged in the same row, and the fourth incoming waveguide parallel and the first incoming waveguide are arranged in the same column,
wherein the third incoming waveguide is connected to an end of the first linear rectangular waveguide so as to be capable of electromagnetic wave communication in parallel with the second curved rectangular waveguide,
wherein the fourth incoming waveguide is connected to an end of the second linear rectangular waveguide so as to be capable of electromagnetic wave communication in parallel with the first curved rectangular waveguide.

7. The plasma generating apparatus using the resonant waveguide of claim 4, wherein each of the linear and curved rectangular waveguides operates in a TE mode,
wherein one of two surfaces of each of the linear and curved rectangular waveguides is perpendicular to an electric field generated in each of the linear and curved rectangular waveguides and vertically extends and faces inwardly of the annular or elliptical shape of the center waveguide,
wherein the slots are defined in an inner side surface of each of the linear rectangular waveguides.

8. The plasma generating apparatus using the resonant waveguide of claim 7, wherein the linear rectangular waveguide is embodied as a WR430 waveguide, wherein the curved rectangular waveguide is embodied as a WR284 waveguide, and wherein the incoming waveguide is embodied as a WR340 waveguide.

9. The plasma generating apparatus using the resonant waveguide of claim 4, wherein the plasma generating apparatus further comprises each guide wall extending into each linear rectangular waveguide from a distal end of an outer side surface of each curved rectangular waveguide perpendicular to an electric field generated in each curved rectangular waveguide, wherein the distal end thereof corresponds to a distal end of each corresponding linear rectangular waveguide.
